(19) United States
(12) Patent Application Publication
(10) Pub. No.: US 2025/0063858 A1
(43) Pub. Date: Feb. 20, 2025

(54) LIGHT EMITTING DIODE AND HORIZONTAL LIGHT EMITTING DEVICE

(71) Applicant: Taiwan-Asia Semiconductor Corporation, Hsinchu City (TW)

(72) Inventor: Kun-Li LIN, Hsinchu City (TW)

(21) Appl. No.: 18/421,571

(22) Filed: Jan. 24, 2024

(30) Foreign Application Priority Data
Aug. 15, 2023 (TW) 112130706

(51) Int. Cl. H01L 33/14; H01L 33/04; H01L 33/40

(52) U.S. Cl. CPC H01L 33/14; H01L 33/04; H01L 33/405

(57) ABSTRACT

The present invention relates to a light-emitting diode (LED) which comprises a light-emitting layer, an upper electrode, a lower electrode, a first semiconductor layer, a second semiconductor layer, a third semiconductor layer, and a low refractive index dielectric layer. The upper electrode and the lower electrode are respectively disposed on two opposite sides of the light-emitting layer. The first semiconductor layer is disposed between the light-emitting layer and the upper electrode. The second semiconductor layer is disposed between the light-emitting layer and the lower electrode. The third semiconductor layer is disposed between the second semiconductor layer and the lower electrode. The low refractive index dielectric layer is disposed to surround the lower electrode. The upper electrode is vertically overlapped with the lower electrode and the first semiconductor layer and the third semiconductor layer are electrically opposite to the second semiconductor layer.

### CROSS-REFERENCES TO RELATED APPLICATIONS

This application claims the benefit of priority to Taiwanese Patent Application No. 112130706 filed on Aug. 15, 2023, which is hereby incorporated by reference in its entirety.

### BACKGROUND OF THE INVENTION

### Field of the Invention

The present invention relates to a light-emitting diode, in particular to a light-emitting diode with high brightness.

### Descriptions of the Related Art

Light-emitting diodes (hereinafter referred to as LED) have the advantages of high brightness, small size, low power consumption and long life, and are widely used in lighting or display products. In order to achieve high brightness, LEDs often use wafer-bonding as a method to increase brightness. Among them, the bottom structure of the epitaxial layer of the wafer-bonded LED has the following characteristics: (1) the bottom structure of the epitaxial layer in the LED has a low refractive index dielectric layer and a reflection metal. Since the lower the refractive index value of the dielectric layer, the more total reflection will occur. Through the function of this dielectric layer and the reflection metal, the light emitted by the active light-emitting layer of the LED will be reflected upward to achieve the purpose of increasing brightness; (2) observing the contact metal or the transparent conductive layer that conducts current at the bottom of the LED, the current conductive points are usually distributed in a point-like or strip-like manner outside the upper electrode to achieve current spreading outside the electrode so that the light generated by the active light-emitting layer will not be blocked by the upper electrode for brightness improvement.

However, the above-mentioned structure has a shortcoming. When the current flows through the active light-emitting layer to emit light, the dielectric layer with a low refractive index is usually not arranged at the position where the current is conducted. Accordingly, the main light-emitting position will not match with the optimal reflection condition resulting in a decrease in overall luminous efficiency. In addition, in the conventional technology, in order to improve the effect of current spreading in the LED, the distance between the active light-emitting layer and the ohmic-contact electrode will not be too large. Generally speaking, the distance between the light-emitting layer and the ohmic-contact electrode will not be greater than 2 microns. However, a too short distance between the light-emitting layer and the ohmic-contact electrode will lead to poor electrical properties of the LED, such as poor antistatic properties and excessive forward voltage.

US Patent Publication No. 2013/0221367A1 discloses a light-emitting diode with a structure similar to the above-mentioned. The position of the metal-contact electrode is arranged outside the upper electrode to spread the current. However, this metal-contact electrode has the above-mentioned problem of absorbing light and affecting LED light extraction. In order to overcome the above problems, the industry urgently needs an innovative light-emitting diode structure and manufacturing process to increase brightness, and at the same time improve related electrical problems such as poor antistatic properties and excessive forward voltage.

### SUMMARY OF THE INVENTION

One main objective of the present invention is to provide a high-brightness light-emitting diode. By adjusting the epitaxial structure, the current will spread away from the electrode to avoid the light emitted from the LED will be blocked by the electrode. Thus, the light extraction efficiency will be improved and the problems such as poor antistatic properties and excessive forward voltage of the conventional light-emitting diode will be solved.

To achieve the above objective, the present invention provides a light-emitting diode comprising a light-emitting layer, an upper electrode and a lower electrode, a first semiconductor layer, a second semiconductor layer, a third semiconductor layer, and a low refractive index dielectric layer. The upper electrode and the lower electrode are respectively disposed on two opposite sides of the light-emitting layer. The first semiconductor layer is disposed between the light-emitting layer and the upper electrode. The second semiconductor layer is disposed between the light-emitting layer and the lower electrode. The third semiconductor layer is disposed between the second semiconductor layer and the lower electrode. The low refractive index dielectric layer is disposed to surround the lower electrode. The upper electrode is vertically overlapped with the lower electrode and the first semiconductor layer and the third semiconductor layer are electrically opposite to the second semiconductor layer.

In one embodiment of the light-emitting diode of the present invention, the light-emitting diode further comprises multiple of epitaxial conductive points, corresponding to the positions of the low refractive index dielectric layer, disposed in the third semiconductor layer, to enable a current flowing from the upper electrode through the first semiconductor layer, the light-emitting layer, the second semiconductor layer, each of the epitaxial conductive points and the third semiconductor layer, into the lower electrode.

In one embodiment of the light-emitting diode of the present invention, each of the epitaxial conductive points is a heavily doped composite layer with tunneling effect. By applying the tunneling effect based on semiconductor physics, the tunneling effect is formed from the N-type semiconductor to the P-type semiconductor under heavy doping conditions in both N-type and P-type semiconductors to achieve the dispersion of current spread away from the electrodes.

In one embodiment of the light-emitting diode of the present invention, the light-emitting diode further comprises a current blocking layer, corresponding to the positions of the upper electrode and the lower electrode, disposed in the second semiconductor layer, for blocking current conduction between the upper electrode and the lower electrode to achieve the dispersion of current spread away from the electrodes.

In one embodiment of the light-emitting diode of the present invention, the current blocking layer is formed by etching a portion of the second semiconductor layer corresponding to the position between the upper electrode and the lower electrode.

In one embodiment of the light-emitting diode of the present invention, the light-emitting diode further comprises a reflection metal layer electrically connected to the lower electrode.

In one embodiment of the light-emitting diode of the present invention, the material of the reflection metal layer is selected from a group consisting of gold (Au), silver (Ag), aluminum (Al), beryllium gold (BeAu), and zinc gold (ZnAu) and a combination thereof.

In one embodiment of the light-emitting diode of the present invention, the material of the low refractive index dielectric layer is selected from a group consisting of silicon dioxide (SiO₂), silicon nitride (Si₃N₄), indium tin oxide (ITO), magnesium fluoride (MgF₂) and a combination thereof.

To achieve the above objective, the present invention provides a horizontal light-emitting device, comprising a light-emitting diode as described in any one of the above-mentioned, a bonding metal layer and an external electrode, wherein the bonding metal layer extending horizontally outward outside the first semiconductor layer, the light-emitting layer, the second semiconductor layer and the third semiconductor layer, and one end of the bonding metal layer is electrically connected to the lower electrode, and the other end of the bonding metal layer is electrically connected to the external electrode.

In one embodiment of the horizontal light-emitting device of the present invention, the horizontal light-emitting device further comprises an insulation substrate bonded with the bonding metal layer.

After reviewing the diagrams and subsequent descriptions, those skilled in the art will readily understand other objectives of the present invention, as well as the technical means and embodiments of the present invention.

### BRIEF DESCRIPTION OF THE DRAWINGS

FIG. 1 to FIG. 10 are process flows of manufacturing a light-emitting diode in one embodiment of the present invention;

FIG. 11 is a top view of a light emitting diode structure in one embodiment of the present invention;

FIG. 12 to FIG. 16 are process flows of manufacturing a light-emitting diodes in another embodiment of the present invention; and

FIG. 17 is a schematic diagram of a horizontal light-emitting device according to one embodiment of the present invention.

### DETAILED DESCRIPTION OF THE PREFERRED EMBODIMENT

The content of the present invention will be explained through examples below. The examples of the present invention are not intended to limit the implementation of the present invention to any specific environment, application, or particular manner as described in the examples. Therefore, the description of the examples is only to elucidate the purpose of the present invention, and not to limit the present invention. It should be noted that in the following examples and figures, components not directly related to the present invention have been omitted and not shown. The dimensional relationships between the components in the figures are provided for ease of understanding and are not intended to limit the actual proportions.

Please refer to FIG. 1, which discloses one embodiment of the present invention, which uses, for example but not limited to, gallium arsenide (GaAs) 100 as a growth substrate for manufacturing a light-emitting diode. Subsequently, a double heterostructure of gallium aluminum indium arsenide (AlGaInAs) is formed on the gallium arsenide substrate. Specifically, in this embodiment, the double heterostructure includes an N-type first semiconductor layer 110, a light-emitting layer 120 formed on the first semiconductor layer 110, and a P-type second semiconductor layer 130 formed on the light-emitting layer 120. The light-emitting layer 120 is a multiple quantum well (MQW) structure, which includes aluminum gallium arsenide (AlGaAs) as the barrier layer for the multiple quantum wells, and indium gallium arsenide (InGaAs) as the well layer for the multiple quantum wells. In addition, the N-type first semiconductor layer 110 is a silicon (Si)-doped aluminum gallium arsenide (AlGaAs) cladding layer, and the P-type second semiconductor layer 130 is a carbon (C)-doped aluminum gallium arsenide (AlGaAs) cladding layer. It should be noted that the materials described in the above embodiment are merely examples, but not used to limit the present invention. In practical applications, materials and their compositions can be adjusted according to the emission wavelength, for example, the epitaxial layers can be aluminum gallium indium phosphide (AlGaInP), indium gallium phosphide (InGaP), aluminum gallium arsenide (AlGaAs), indium gallium arsenide (InGaAs), or indium phosphide (InP), or the like.

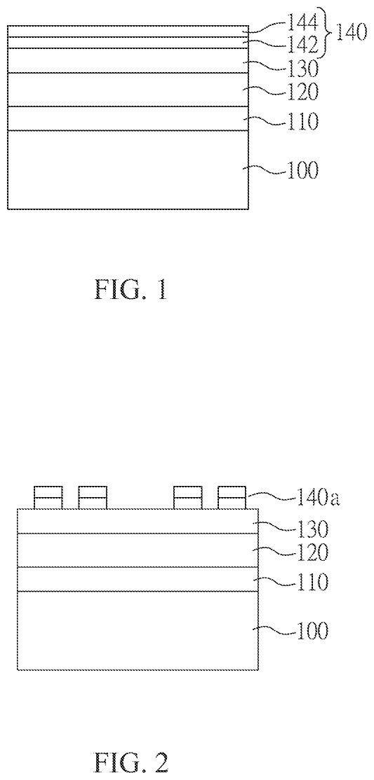

Please continue to refer to FIG. 1. A heavily doped composite layer with tunneling effect 140 is formed on the P-type second semiconductor layer 130. This heavily doped composite layer with tunneling effect 140 includes a P-type epitaxial layer 142 and an N-type epitaxial layer 144. The P-type epitaxial layer 142 can be an extremely heavily carbon (C)-doped gallium arsenide (GaAs) epitaxial layer, and the N-type epitaxial layer 144 can be an extremely heavily tellurium (Te)-doped gallium arsenide (GaAs) epitaxial layer. After forming the heavily doped composite layer with tunneling effect 140 on the P-type second semiconductor layer 130, a photolithography process is carried out to pattern this heavily doped composite layer 140. This patterned heavily doped composite layer 140, in subsequent operation of the light-emitting diode, due to the tunneling effect generated between the N-type semiconductor and the P-type semiconductor, forms multiple epitaxial conductive points 140a, achieving the effect of spreading the current, as shown in FIG. 2.

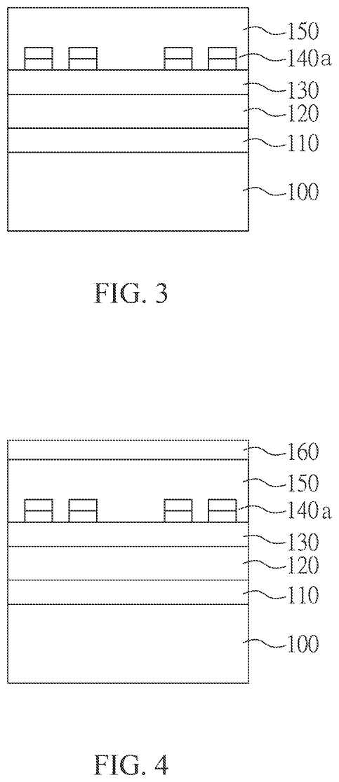

Next, please refer to FIG. 3. Further perform an epitaxial growth and doping process to form an N-type third semiconductor layer 150. In this case, the third semiconductor layer 150 will fill the patterned heavily doped composite layer 140, and continue to cover the entire second semiconductor layer 130 to a considerable thickness. In a specific embodiment, the third semiconductor layer 150 can be a silicon (Si)-doped gallium arsenide (GaAs) epitaxial layer.

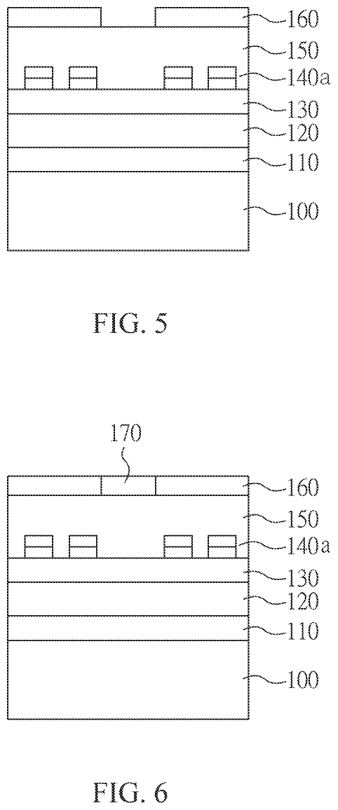

As shown in FIG. 4, a dielectric layer 160 is formed on the third semiconductor layer 150. Specifically, this dielectric layer 160 is a low refractive index dielectric layer, and its material can be selected from a group consisting of silicon dioxide (SiO₂), silicon nitride (Si₃N₄), indium tin oxide (ITO), magnesium fluoride (MgF₂) and their combination. Next, the low refractive index dielectric layer 160 undergoes a patterned etching process to define the position of the lower electrode formed in the following process, as shown in FIG. 5. It is important to emphasize that in this step, the patterned dielectric layer 160 will cover the patterned heavily doped composite layer 140 in the vertical position, that is, it will cover multiple epitaxial conductive points 140a.

Please refer to FIG. 6. Next, a metal evaporation process is carried out to form a lower electrode 170. This lower electrode 170 will fill the recessed area in the dielectric layer 160 that was removed by the etching process as shown in FIG. 5. As a result, the lower electrode 170 is surrounded by the patterned low refractive index dielectric layer 160. Moreover, this lower electrode 170 is a P-type electrode, serving as the ohmic-contact metal. As mentioned earlier, the position and patterned structure of the lower electrode 170 are defined by the dielectric layer 160. Therefore, the multiple epitaxial conductive points 140a do not overlap with the lower electrode 170 in the vertical position.

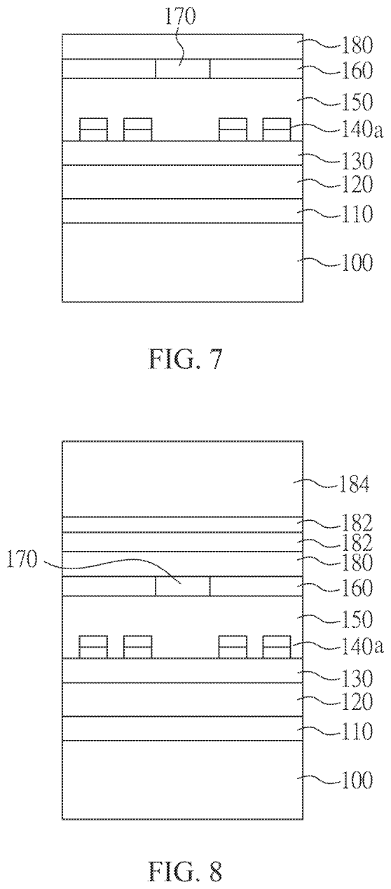

Please refer to FIG. 7. After forming the lower electrode 170, the metal evaporation process is carried out to form a reflection metal layer 180. The reflection metal layer 180 covers the low refractive index dielectric layer 160 and the lower electrode 170, and electrically connects to the lower electrode 170. In practical applications, both the lower electrode 170 and the reflection metal layer 180 can be made of the same conductive material, which can be generally selected from a group consisting of gold (Au), silver (Ag), aluminum (Al), beryllium gold (BeAu), and zinc gold (ZnAu) and their combination. The reflection metal layer 180, combined with the aforementioned low refractive index dielectric layer 160, can enhance the reflection efficiency of light emitted from the light-emitting layer 120.

Please refer to FIG. 8. Above the lower electrode 170 and the reflection metal layer 180, a bonding metal layer 182 for subsequent bonding to the permanent bonding substrate is formed by evaporation. Similarly, a bonding metal layer 182 is also evaporated to be deposited on the permanent bonding substrate 184. The bonding metal material can be gold (Au) or an indium-gold (InAu) alloy. The permanent bonding substrate 184 can be, but not limited to, a silicon substrate or a sapphire substrate. Subsequently, the light-emitting diode structure on the epitaxial substrate 100 is metal-bonded to the permanent bonding substrate 184 by means of the bonding metal layer 182.

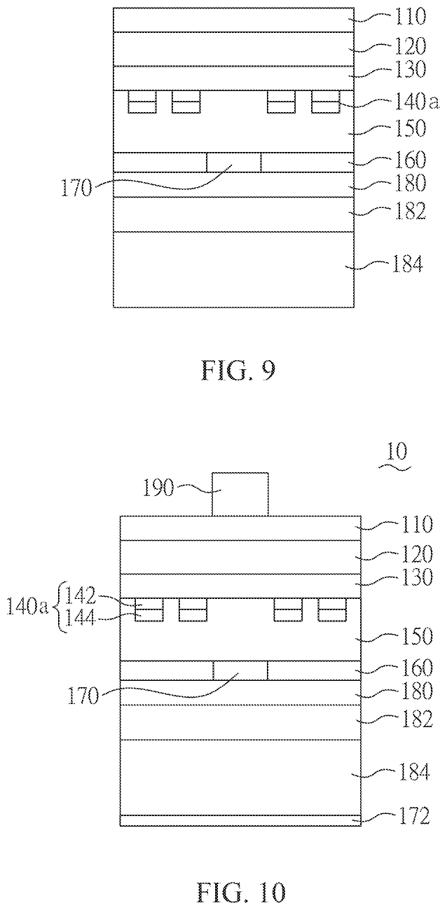

Please refer to FIG. 9. The gallium arsenide (GaAs) epitaxial substrate 100 is removed to expose the first semiconductor layer 110, and the structure is flipped so that the permanent bonding substrate 184 is disposed at the bottom of the light-emitting diode structure. Next, please refer to FIG. 10. A MESA process is carried out to etch a portion of the epitaxial composite layer to form cutting paths on the permanent bonding substrate 184. Additionally, a patterned upper electrode 190 is formed on the first semiconductor layer 110. This upper electrode 190 is electrically opposite to the lower electrode 170. The upper electrode 190, which is an N-type electrode, has a material selected from a group consisting of germanium (Ge), titanium (Ti), platinum (Pt), and gold (Au) and their combination. It is noted that the upper electrode 190 overlaps with the lower electrode 170 in their vertical positions, and both have similar patterned structures. Furthermore, a back electrode 172 is formed on the other side of the permanent bonding substrate 184 and electrically connected to the lower electrode 170. A final structure of the light-emitting diode 10 according to the present invention is completed accordingly.

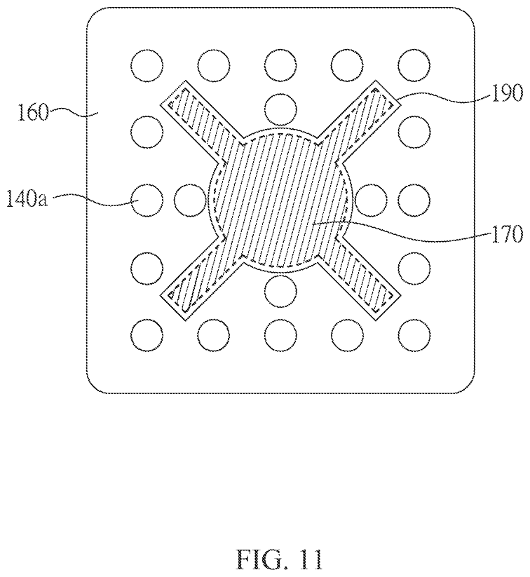

Please refer to both FIG. 10 and FIG. 11. FIG. 11 is the top view of FIG. 10, showing the relationship between multiple epitaxial conductive points 140a, the upper electrode 190 on the low refractive index dielectric layer 160, and the lower electrode 170 (as indicated by the dashed lines in FIG. 11) in terms of their positions and pattern structures. Since a plurality of epitaxial conduction points 140a having the tunneling effect are provided in the third semiconductor layer 150 of the light-emitting diode 10 of the present invention, the tunneling effect generated between the N-type epitaxial layer 144 and the P-type epitaxial layer 142 is utilized so the injected current will flow from the upper electrode 190 through the first semiconductor layer 110, the light-emitting layer 120, and the second semiconductor layer 130, and then be guided and spread by the epitaxial conduction points 140a, and then flow into the third semiconductor layer 150 and lower electrode 170. Thus, the current spreading effect generated by the plurality of epitaxial conduction points 140a can be achieved. More specifically, each epitaxial conduction point 140a overlaps with the low refractive index dielectric layer 160 in a vertical position. When the injected current spreads through the light-emitting layer to the epitaxial conduction point 140a, most of the light, emitted downwards from the light-emitting layer and passed through the low refractive index dielectric layer, will be reflected upward in a manner of the best reflection efficiency without being blocked by the upper electrode 190. Therefore, the light extraction efficiency of the light-emitting diode is improved. In addition, it should be noted that since the first semiconductor layer 110 and the third semiconductor layer 150 both belong to the N-type and have opposite electrical properties with the P-type second semiconductor layer 130, the P-type second semiconductor layer 130 and the N-type third semiconductor layer 150 will act like a reverse diode, it can be ensured that there is no conduction between the upper electrode 190 and the lower electrode 170 to worsen the light extraction efficiency.

In a preferred embodiment, the thickness of the aforementioned third semiconductor layer 150 is at least 2 micrometers or more, and it may even reach up to 8 micrometers. The thickened third semiconductor layer 150 in a complete structure of the light-emitting diode increases the distance between the light-emitting layer 120 and the lower electrode 170. This enhances the electrostatic discharge (ESD) resistance of the light-emitting diode, and thereby, overcomes the drawbacks of current crowding effects and reduced ESD resistance in conventional light-emitting diode structures caused by the excessively short distance between the light-emitting layer and the lower electrode.

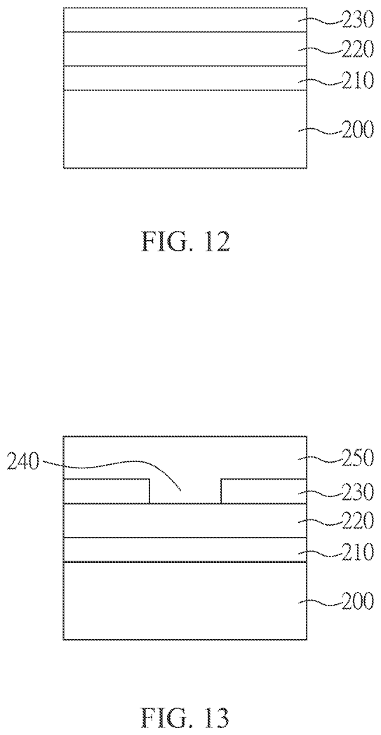

In addition to the disclosed embodiment above, another embodiment of a light-emitting diode of the present invention will be described. Please refer to FIG. 12. Similar to the previous embodiment, a gallium arsenide (GaAs) substrate 200 is used as a growth substrate. A gallium aluminum indium arsenide (GaAlInAs) double heterostructure is formed on the GaAs substrate, which includes an N-type first semiconductor layer 210, a light-emitting layer 220, and a P-type second semiconductor layer 230. The light-emitting layer 220 is formed on the first semiconductor layer 210, and the P-type second semiconductor layer 230 is formed on the light-emitting layer 220. The material and their composition of the light-emitting layer 220, the first semiconductor layer 210, and the second semiconductor layer 230 are the same as the previous embodiment. Further elaboration is omitted.

Please refer to FIG. 13. A patterning process is carried out on the P-type second semiconductor layer 230. For example, a photolithographic wet etching process is performed to remove a portion of the P-type second semiconductor layer 230 and to form a patterned recessed region 240 until a portion of the surface of the light-emitting layer 220 is partially exposed. Subsequently, epitaxial growth and doping processes are carried out again to form an N-type third semiconductor layer 250. In this case, the third semiconductor layer 250 will fill the patterned recessed region 240 formed by the patterning process, and continue to cover the entire second semiconductor layer 230 to a considerable thickness. In a specific embodiment, the third semiconductor layer 250 can be a silicon-doped gallium arsenide epitaxial layer. In a preferred embodiment, the thickness of the third semiconductor layer 250 is at least 2 micrometers, and may even reach 8 micrometers.

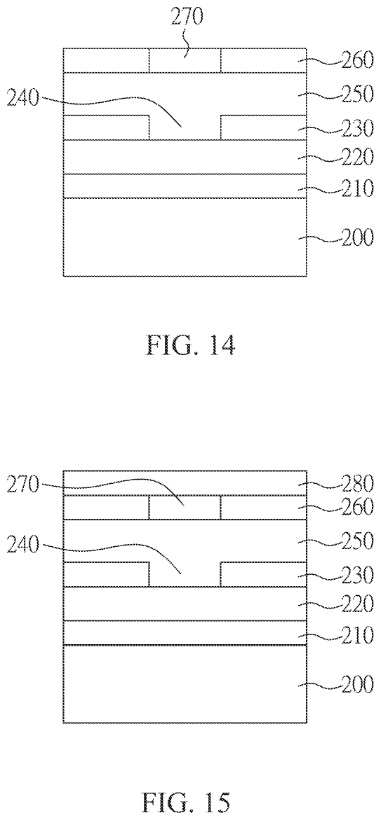

As shown in FIG. 14, a dielectric layer 260 is formed on the third semiconductor layer 250. Specifically, the dielectric layer 260 is a low refractive index dielectric layer, and its material can be selected from a group consisting of silicon dioxide, silicon nitride, indium tin oxide, and magnesium fluoride and their combination. Subsequently, a patterning etching process is performed on the low refractive index dielectric layer 260 to locate the position of the lower electrode 270. Next, a metal evaporation process is carried out to form the lower electrode 270, which is surrounded by the low refractive index dielectric layer 260. The lower electrode 270 is a P-type electrode, serving as the ohmic-contact metal. It should be noted that the position of the lower electrode 270 and the patterned structure are determined by the patterning process of the dielectric layer 260. During the patterning of the dielectric layer 260, it is necessary to position the subsequent formation of the lower electrode 270 relative to the patterned structure at the vertical position of the recessed region 240 in the third semiconductor layer 250, so that the patterned structure of the lower electrode 270 and the recessed region 240 are substantially the same.

Please refer to FIG. 15. After forming the lower electrode 270, a metal evaporation process is carried out to form a reflective metal layer 280. The reflective metal layer 280 covers the low refractive index dielectric layer 260 and the lower electrode 270, and electrical connects to the lower electrode 270. In practical applications, the lower electrode 270 and the reflective metal layer 280 can be made of the same conductive materials which can be selected from a group consisting of gold, silver, aluminum, beryllium gold, and zinc gold, individually and their combination.

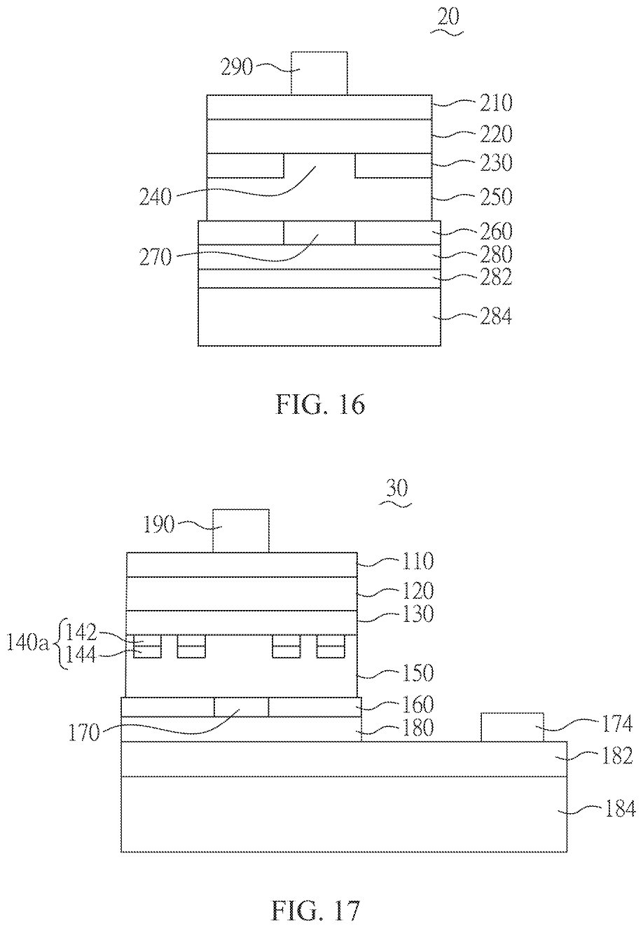

Subsequent processes are similar to the previous embodiment. Please refer to FIG. 16. Similar to the previous embodiment, a bonding metal layer 282 and a permanent bonding substrate 284 are successively formed on the lower electrode 270 and the reflective metal layer 280. The epitaxial substrate 200 is then removed. Subsequently, a MESA process is carried out, and a patterned upper electrode 290 is formed on the first semiconductor layer 210 to create the final structure of the light-emitting diode 20 in the second embodiment. The material of the upper electrode 290 can be selected from a group consisting of germanium, titanium, platinum, and gold, individually and their combination. Similarly, in this embodiment, the upper electrode 290 is positioned above the patterned recessed area 240 in the third semiconductor layer 250, and its patterned structure is generally similar to that of the recessed area 240 and the lower electrode 270.

In the aforementioned structure, the recessed area 240 is designed to align vertically with the upper electrode 290 and the lower electrode 270. The recessed area 240 has a good current blocking effect due to the destruction of the epitaxial structure during the etching process. When the light-emitting diode 20 is under normal operation, the recessed area 240 will act as a current blocking layer to ensure that there will be no direct current flow between the upper electrode and the lower electrode. The injected current will be spread outside the recessed area 240 and then dispersed throughout the entire LED structure. In addition, the recessed area 240 cooperates with the low refractive index dielectric layer 260 outside the lower electrode 270 so that most of the light emitted downwards from the light-emitting layer will pass through the low refractive index dielectric layer with the best reflection efficiency, and then be reflected upward without being blocked by the upper electrode 290. Therefore, the light extraction efficiency of the light-emitting diode 20 can be improved and the brightness of the light-emitting diode 20 can be increased.

Although the above embodiment illustrates the technical features of the present invention with a vertical light-emitting diode structure, it should be noted that the light-emitting diode of the present invention is not limited to a vertical structure. Please refer to FIG. 17, which specifically shows an embodiment of applying the above light-emitting diode structure to a horizontal light-emitting diode structure. FIG. 17 depicts a horizontal light-emitting device 30, whose epitaxial structure is similar to the above embodiment. The only difference is that the bonding metal layer 182 extends horizontally relative to the other epitaxial layers, encompassing the first semiconductor layer 110, the light-emitting layer 120, the second semiconductor layer 130, and the third semiconductor layer 150. One end of the bonding metal layer 182 is electrically connected to the lower electrode 170, while the other end is electrically connected to an external electrode 174. The permanent bonding substrate 184 connected to the bonding metal layer 182 is an insulation substrate. The rest of the epitaxial structure can be referred to in the above content, and will not be repeated here.

The above embodiments are provided for illustrative purposes and to explain the technical features of the present invention, and are not intended to limit the scope of protection of the present invention. Any modifications or equivalents that can be easily made by those skilled in the art are within the scope claimed by the present invention, and the scope of protection of the present invention shall be determined by the scope of the patent application.

What is claimed is:

1. A light-emitting diode, comprising:
a light-emitting layer;
an upper electrode and a lower electrode respectively disposed on two opposite sides of the light-emitting layer;
a first semiconductor layer disposed between the light-emitting layer and the upper electrode;
a second semiconductor layer disposed between the light-emitting layer and the lower electrode;
a third semiconductor layer disposed between the second semiconductor layer and the lower electrode; and
a low refractive index dielectric layer disposed to surround the lower electrode,
wherein the upper electrode is vertically overlapped with the lower electrode, and the first semiconductor layer and the third semiconductor layer are electrically opposite to the second semiconductor layer.

2. The light-emitting diode of claim 1, further comprising multiple of epitaxial conductive points, corresponding to the positions of the low refractive index dielectric layer, disposed in the third semiconductor layer, to enable a current flowing from the upper electrode through the first semiconductor layer, the light-emitting layer, the second semiconductor layer, each of the epitaxial conductive points and the third semiconductor layer, into the lower electrode.

3. The light-emitting diode of claim 2, wherein each of the epitaxial conductive points is a heavily doped composite layer with tunneling effect.

4. The light-emitting diode of claim 1, further comprising a current blocking layer, corresponding to the positions of the upper electrode and the lower electrode, disposed in the second semiconductor layer, for blocking current conduction between the upper electrode and the lower electrode.

5. The light-emitting diode of claim 4, wherein the current blocking layer is formed by etching a portion of the second semiconductor layer corresponding to the position between the upper electrode and the lower electrode.

6. The light-emitting diode of claim 1, further comprising a reflection metal layer electrically connected to the lower electrode.

7. The light-emitting diode of claim 6, wherein the material of the reflection metal layer is selected from a group consisting of gold (Au), silver (Ag), aluminum (Al), beryllium gold (BeAu), and zinc gold (ZnAu) and a combination thereof.

8. The light-emitting diode of claim 1, wherein the material of the low refractive index dielectric layer is selected from a group consisting of silicon dioxide (SiO₂), silicon nitride (Si₃N₄), indium tin oxide (ITO), magnesium fluoride (MgF₂) and a combination thereof.

9. A horizontal light-emitting device, comprising:
a light-emitting diode as described in claim 1;
a bonding metal layer; and
an external electrode,
wherein the bonding metal layer extending horizontally outward outside the first semiconductor layer, the light-emitting layer, the second semiconductor layer and the third semiconductor layer, and one end of the bonding metal layer is electrically connected to the lower electrode, and the other end of the bonding metal layer is electrically connected to the external electrode.

10. The horizontal light-emitting device of claim 9, further comprising an insulation substrate bonded with the bonding metal layer.
